(19) United States
(12) Patent Application Publication
(10) Pub. No.: US 2025/0107391 A1
(43) Pub. Date: Mar. 27, 2025

(54) DISPLAY DEVICE

(71) Applicants: Samsung Display Co., LTD., Yongin-si (KR); SEOUL NATIONAL UNIVERSITY OF SCIENCE AND TECHNOLOGY, Seoul (KR)

(72) Inventors: Ji Yoon KIM, Yongin-si (KR); Hyunsik YOON, Seoul (KR)

(73) Assignees: Samsung Display Co., LTD., Yongin-si (KR); SEOUL NATIONAL UNIVERSITY OF SCIENCE AND TECHNOLOGY, Seoul (KR)

(21) Appl. No.: 18/642,327

(22) Filed: Apr. 22, 2024

(30) Foreign Application Priority Data
Sep. 27, 2023 (KR) 10-2023-0131082

(51) Int. Cl. H10K 59/70; H10K 59/122; H10K 59/80

(52) U.S. Cl. CPC H10K 59/70; H10K 59/122; H10K 59/873

(57) ABSTRACT

A display device includes a first substrate including a light emitting area and a non-light emitting area, a first pixel electrode disposed on the light emitting area of the first substrate, a pixel defining layer disposed on the non-light emitting area of the first substrate and the first pixel electrode, a light emitting structure disposed on the first pixel electrode and including quantum dots, and a common electrode covering the light emitting structure and the pixel defining layer, wherein the pixel defining layer includes an inorganic insulating material layer including a fluorine-based material.

### CROSS-REFERENCE TO RELATED APPLICATION(S)

This application claims priority to and benefits of Korean Patent Application No. 10-2023-0131082 under 35 U.S.C. 119, filed on Sep. 27, 2023, in the Korean Intellectual Property Office (KIPO), the entire contents of which are incorporated herein by reference.

### BACKGROUND

### 1. Technical Field

The disclosure relates to a display device.

### 2. Description of the Related Art

As an information society develops, the demand for a display device for displaying an image is increasing in various forms. For example, display devices are applied to various electronic devices such as smartphones, digital cameras, laptop computers, navigation devices, and smart televisions.

The display device may be a flat panel display device such as a liquid crystal display device, a field emission display device, or a light emitting display device. The light emitting display device may include an organic light emitting display device including an organic light emitting element and an inorganic light emitting display device including an inorganic light emitting element such as quantum dots.

Development of a display device including quantum dots among such display devices is in progress, and efforts to improve efficiency of the display device using the quantum dots are continuously being made.

### SUMMARY

Aspects of the disclosure provide a display device capable of improving reliability of light emitting elements by preventing diffusion of impurities into the light emitting elements including a quantum dot light emitting layer, and a pixel defining layer.

Aspects of the disclosure also provide a display device capable of increasing durability of light emitting elements by preventing bonding of ligands of organic or inorganic compounds included in a quantum dot light emitting layer.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, a display device may include a first substrate including a light emitting area and a non-light emitting area, a first pixel electrode disposed on the light emitting area of the first substrate, a pixel defining layer disposed on the non-light emitting area of the first substrate and the first pixel electrode, a light emitting structure disposed on the first pixel electrode and including quantum dots, and a common electrode covering the light emitting structure and the pixel defining layer. The pixel defining layer may include a first inorganic insulating material layer including a fluorine-based material.

In an embodiment, the display device may further include an encap structure disposed on the common electrode, overlapping the non-light emitting area in a thickness direction of the first substrate, and in contact with the common electrode. The encap structure may include a second substrate and a hydrogen donor layer disposed between the second substrate and the common electrode, the hydrogen donor layer may overlap the light emitting area in the thickness direction and may be spaced apart from the common electrode, and a space may be interposed between the hydrogen donor layer and the common electrode.

In an embodiment, the hydrogen donor layer may include at least one of silicon nitride and silicon oxide, and the hydrogen donor layer may further include a hydrogen atom forming one of a silicon-hydrogen (Si—H) bond, a nitrogen-hydrogen (N—H) bond, and an oxygen-hydrogen (O—H) bond.

In an embodiment, the light emitting structure may further include a quantum dot light emitting layer and an electron transporting layer, the light emitting structure may have an inclined portion inclined in a direction toward the common electrode at a portion in contact with the pixel defining layer, and the electron transporting layer may include zinc oxide.

In an embodiment, the pixel defining layer may further include a second inorganic insulating material layer including silicon, and may be formed as a double layer with the second inorganic insulating material layer covering the first inorganic insulating material layer.

In an embodiment, the second inorganic insulating material layer may include at least one of silicon oxide (SiO₂), silicon nitride (Si₃N₄), and silicon oxynitride (Si₂N₂O), and the first inorganic insulating material layer may include at least one of fluorine-based silicon oxide (F-SiO₂), fluorine-based silicon nitride (F-Si₃N₄), and fluorine-based silicon oxynitride (F-Si₂N₂O).

In an embodiment, the pixel defining layer may further include an organic insulating material layer including silicon, and may be formed as a double layer with the organic insulating material layer covering the first inorganic insulating material layer.

In an embodiment, the organic insulating material layer may include at least one of a polyacrylates resin, an epoxy resin, a phenolic resin, a polyamides resin, a polyimides resin, an unsaturated polyesters resin, a polyphenylenethers resin, a polyphenylenesulfides resin, and benzocyclobutene (BCB), and the first inorganic insulating material layer may include at least one of fluorine-based silicon oxide (F-SiO₂), fluorine-based silicon nitride (F-Si₃N₄), and fluorine-based silicon oxynitride (F-Si₂N₂O).

According to an embodiment of the disclosure, a display device may include a first substrate including a light emitting area and a non-light emitting area, a first pixel electrode disposed on the light emitting area of the first substrate, a pixel defining layer disposed on the non-light emitting area of the first substrate and the first pixel electrode, a light emitting structure disposed on the first pixel electrode and including quantum dots, a common electrode covering the light emitting structure and the pixel defining layer, and an encap structure disposed on the common electrode, overlapping the non-light emitting area in a thickness direction of the first substrate, and in contact with the common electrode,

In an embodiment, the pixel defining layer may be formed as a double layer including an organic insulating material layer or a first inorganic insulating material layer disposed on the non-light emitting area of the first substrate, and a second inorganic insulating material layer covering the organic insulating material layer or the first inorganic insulating material layer.

In an embodiment, the encap structure may include a second substrate and a hydrogen donor layer disposed between the second substrate and the common electrode, the hydrogen donor layer may overlap the light emitting area in the thickness direction and may be spaced apart from the common electrode, and a space may be interposed between the hydrogen donor layer and the common electrode.

In an embodiment, the hydrogen donor layer may include at least one of silicon nitride and silicon oxide, and the hydrogen donor layer may further include a hydrogen atom forming one of a silicon-hydrogen (Si—H) bond, a nitrogen-hydrogen (N—H) bond, and an oxygen-hydrogen (O—H) bond.

In an embodiment, the light emitting structure may further include a quantum dot light emitting layer and an electron transporting layer, the light emitting structure may have an inclined portion inclined in a direction toward the common electrode at a portion in contact with the pixel defining layer, and the electron transporting layer may include zinc oxide.

In an embodiment, the pixel defining layer may be formed as a double layer with the organic insulating material layer or the first inorganic insulating material layer covering the second inorganic insulating material layer including a fluorine-based material.

In an embodiment, the first inorganic insulating material layer may include at least one of silicon oxide (SiO₂), silicon nitride (Si₃N₄), and silicon oxynitride (Si₂N₂O), and the second inorganic insulating material layer may include at least one of fluorine-based silicon oxide (F-SiO₂), fluorine-based silicon nitride (F-Si₃N₄), and fluorine-based silicon oxynitride (F-Si₂N₂O).

In an embodiment, the organic insulating material layer may include at least one of a polyacrylates resin, an epoxy resin, a phenolic resin, a polyamides resin, a polyimides resin, an unsaturated polyesters resin, a polyphenylenethers resin, a polyphenylenesulfides resin, and benzocyclobutene (BCB).

According to the display device according to embodiments, reliability of light emitting elements may be improved by preventing diffusion of impurities into the light emitting elements including a quantum dot light emitting layer, and a pixel defining layer.

In addition, durability of light emitting elements may be increased by preventing bonding of ligands of organic or inorganic compounds included in a quantum dot light emitting layer.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a display device according to an embodiment; FIG. 2 is a plan view of a display device according to an embodiment;

FIG. 3 is a schematic cross-sectional view of a display panel of FIG. 2 taken along line I-I′;

FIG. 4 is an enlarged plan view of area ‘A’ of FIG. 2;

FIG. 5 is a schematic cross-sectional view of the display device taken along line X1-X1′ of FIG. 4;

FIG. 6 is a schematic cross-sectional view illustrating a deposition process of a pixel defining layer of FIG. 5;

FIG. 7 is a schematic cross-sectional view illustrating a patterning result of the pixel defining layer of FIG. 6;

FIG. 8 is an enlarged schematic cross-sectional view of a first light emitting area of the display device illustrated in FIG. 5;

FIGS. 9 and 10 are perspective views illustrating a quantum dot display device including a quantum dot light emitting layer according to an embodiment;

FIGS. 11 and 12 are perspective views illustrating a quantum dot display device according to another embodiment of the disclosure;

FIG. 13 is a perspective view illustrating a rollable type quantum dot display device according to another embodiment of the disclosure; and

FIG. 14 is a perspective view illustrating a rollable type quantum dot display device according to another embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

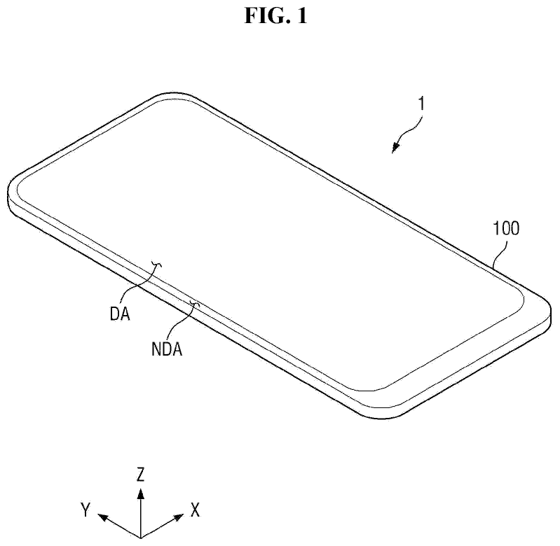

FIG. 1 is a perspective view illustrating a display device according to an embodiment. FIG. 2 is a plan view of a display device according to an embodiment.

Referring to FIG. 1, a display device 1 may display a moving image or a still image. The display device 1 may be an electronic device that provides a display screen. For example, the display device 1 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that provide a display screen.

Examples of the display device 1 may include an inorganic light emitting diode display device, an organic light emitting display device, a quantum dot light emitting display device, a plasma display device, and a field emission display device. Hereinafter, it is illustrated that an organic light emitting diode display device is used as an embodiment of the display device, but the disclosure is not limited thereto, and the disclosure may also be applied to other display devices as long as the same technical idea is applicable thereto.

A shape of the display device 1 may be variously changed. For example, the display device 1 may have a shape such as a rectangle with a long width, a rectangle with a long length, a square, a quadrangle with rounded corners (vertices), other polygons, or a circle in a plan view. A shape of a display area DA of the display device 1 may be similar to an overall shape of the display device 1. In FIG. 1, the display device 1 having a rectangular shape with a long length in a second direction Y is illustrated, but the display device 1 is not limited thereto.

Referring to FIGS. 1 and 2, the display device 1 may include a display panel 100, a display driver 200, and a circuit board 300.

The display panel 100 may be formed in a rectangular planar shape having short sides in a first direction (X-axis direction) and long sides in a second direction (Y-axis direction) intersecting the first direction (X-axis direction) in a plan view. A corner where the short side in the first direction (X-axis direction) and the long side in the second direction (Y-axis direction) meet may be rounded to have a curvature or may be formed at a right angle. The planar shape of the display panel 100 is not limited to the quadrangular shape, and may be formed in other polygonal shapes, a circular shape, or an elliptical shape. The display panel 100 may be formed to be flat, but the disclosure is not limited thereto, and the display panel 100 may include curved portions formed at left and right ends and having a constant curvature or a varying curvature. The display panel 100 may be flexibly formed to be curved, bendable, foldable, or rollable.

The display panel 100 may include a display area DA, a non-display area NDA, and a pad area PDA.

The display area DA may generally occupy the center of the display device 1. Multiple pixels PX may be disposed in the display area DA. Each of the pixels PX may be defined as a minimum unit emitting light. The pixels PX may be connected to signal lines positioned in the non-display area NDA. The display area DA may emit light from light emitting areas EA included in the pixels PX or from multiple openings OP.

The non-display area NDA may be an area adjacent to the display area DA. The non-display area NDA may be an area outside an edge of the display panel 100 and may be an area surrounding the display area DA. The non-display area NDA may include a gate driver (not illustrated) supplying gate signals to gate lines, and fan-out lines (not illustrated) connecting the display driver 200 and the display area DA.

The display driver 200 may output signals and voltages for driving the display panel 100. Specifically, the display driver 200 may output signals and voltages for driving the pixels PX disposed in the display area DA. The display driver 200 may supply data voltages to data lines of the display panel 100. The display driver 200 may supply a power voltage to a power line and may supply a gate control signal to a gate driver of the display panel 100.

The circuit board 300 may be attached onto the pad portion of the display panel 100 using an anisotropic conductive film (ACF). Lead lines of the circuit board 300 may be electrically connected to the pad portion of the display panel 100. The circuit board 300 may be a flexible film such as a flexible printed circuit board, a printed circuit board, or a chip on film. The display driver 200 may be formed as an integrated circuit (IC) and mounted on the display panel 100 by a chip on glass (COG) method, a chip on plastic (COP) method, or an ultrasonic bonding method. The display driver 200 may be formed as an integrated circuit (IC) and mounted on the circuit board 300 by a chip on glass (COG) method, a chip on plastic (COP) method, or an ultrasonic bonding method. However, the disclosure is not limited thereto, and in another embodiment, the display driver 200 may be mounted on the display panel 100 by a COG method, a COP method, or an ultrasonic bonding method.

Multiple display pads PD may be disposed in the pad area PDA of the display panel 100. The display pads PD may be disposed at an edge of the pad area PDA. The display pads PD may be connected to a graphic system through the circuit board 300. The display pad PD may be connected to the circuit board 300 to receive digital video data and supply the digital video data to the display driver 200.

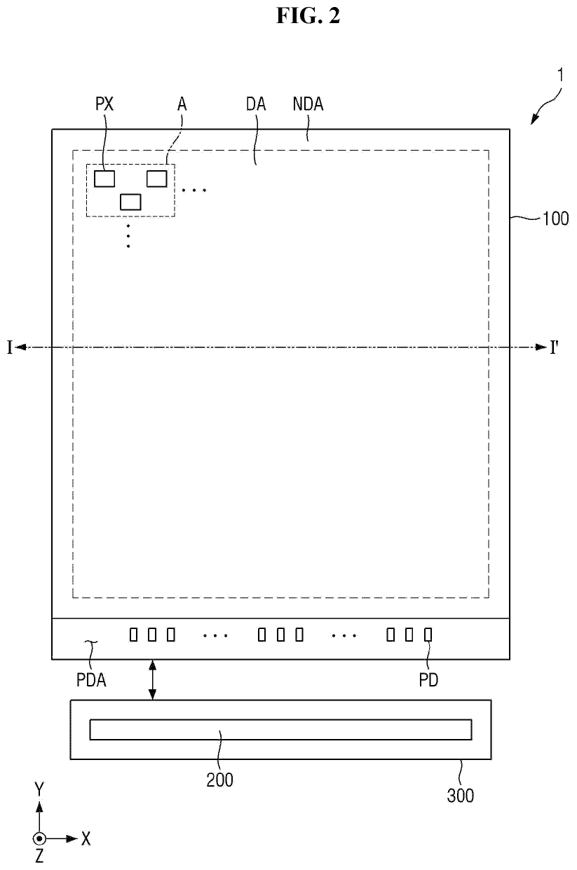

FIG. 3 is a schematic cross-sectional view of a display panel of FIG. 2 taken along line I-I′.

A schematic stacked structure of the display device 1 will be described with reference to FIG. 3. The display device 1 may include a first substrate 10, a second substrate 30 facing the first substrate 10, and a sealing portion 50 that couples the first substrate 10 and the second substrate 30. The first substrate 10 may include a first base substrate 110 and a light emitting element layer 150, and the second substrate 30 may include a second base substrate 310 and a hydrogen donor layer 330.

The first base substrate 110 may be a base substrate or a base member. The first base substrate 110 may be a flexible substrate that may be bent, folded, or rolled. In an embodiment, the first base substrate 110 may include a polymer resin including polyimide PI, but the disclosure is not limited thereto. In another embodiment, the first base substrate may include a glass material or a metal material.

The light emitting element layer 150 may include a pixel circuit including switching elements, a pixel defining layer defining the light emitting areas or the opening areas, and a self-light emitting element. For example, the self-light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED.

The second base substrate 310 may be formed of a material such as glass, metal, or plastic such as polyethylene terephthalate (PET), polyethylene naphthalate (PEN), or polyimide. The second substrate 30 may include ultra thin glass (UTG) with a thickness less than or equal to about 0.01 mm. The second substrate 30 may prevent impurities such as moisture or air from permeating from the outside and diffusing into the light emitting element layer 150 of the first substrate 10.

The hydrogen donor layer 330 may be disposed on the second base substrate 310. The hydrogen donor layer 330 may be deposited on the second base substrate 310 and bonded with the first substrate 10 via the sealing portion 50 through a subsequent process. Accordingly, the hydrogen donor layer 330 may be positioned between the first base substrate 110 and the second base substrate 310. The hydrogen donor layer 330 may face the light emitting element layer 150 and overlap the light emitting element layer 150 in a plan view.

The hydrogen donor layer 330 may be an inorganic layer including silicon. For example, the hydrogen donor layer 330 may include at least one of silicon oxide (SiO₂), silicon nitride (Si₃N₄), silicon oxynitride (Si₂N₂O).

The sealing portion 50 may be disposed in the non-display area NDA and along edges of the first substrate 10 and the second substrate 30 surrounding the display area DA in a plan view. The first substrate 10 and the second substrate 30 may be coupled to each other via the sealing portion 50. The sealing portion 50 may prevent impurities such as moisture or air from permeating from the outside and diffusing into the light emitting element layer 150 of the first substrate 10. The scaling portion 50 may include both an organic material such as an epoxy resin and an inorganic material such as a glass.

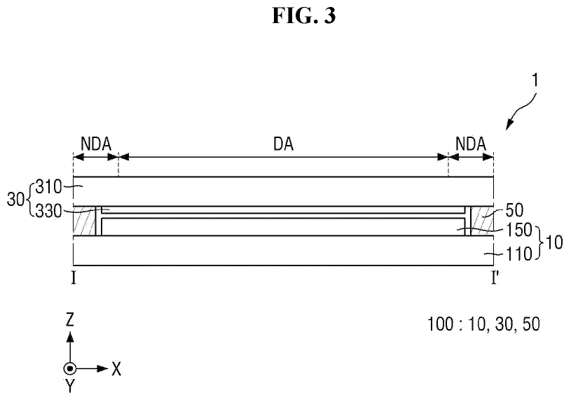

FIG. 4 is an enlarged plan view of area ‘A’ of FIG. 2.

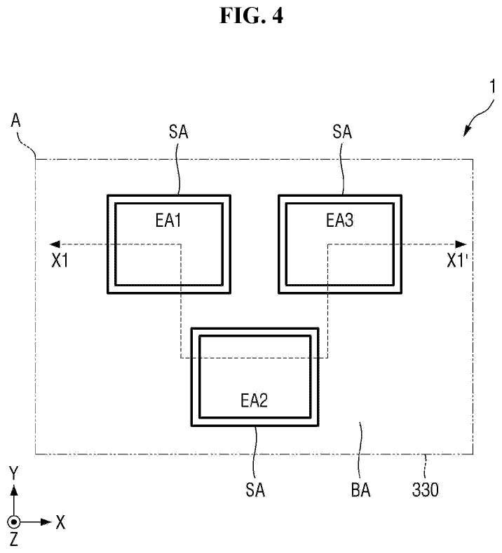

Referring to FIG. 4, the display device 1 may include multiple light emitting areas EA1, EA2, and EA3 disposed in the display area DA. The light emitting areas EA1, EA2, and EA3 may include a first light emitting area EA1, a second light emitting area EA2, and a third light emitting area EA3 that emit light of different colors. The light emitting areas EA1, EA2, and EA3 may each emit red, green, or blue light, and the color of light emitted from each of the light emitting areas EA1, EA2, and EA3 may be set depending on the types of light emitting elements ('ED1′, ‘ED2’, and ‘ED3’ in FIG. 5) disposed in the light emitting element layer (150 in FIG. 5) of each of the light emitting areas EA1, EA2, and EA3. In an embodiment, the first light emitting area EA1 may emit first light of a red color, the second light emitting areas EA2 may emit second light of a green color, and the third light emitting areas EA3 may emit third light of a blue color.

A non-light emitting area BA is an area surrounding each of the light emitting areas EA1, EA2, and EA3. The non-light emitting area BA may be an area through which light does not pass, but the disclosure is not limited thereto. Light may or may not pass through the non-light emitting area BA depending on the material included in the pixel defining layer (‘151’ in FIG. 5), which will be described below.

In some embodiments, the display device 1 may include spaces SA surrounding each of the light emitting areas EA1, EA2, and EA3. Each space SA may be generated by bonding the first substrate 10 and the second substrate 30. Each space SA may be filled with nitrogen gas (N₂) or air (Air) depending on the atmosphere of the manufacturing process. The space SA will be described in detail below.

In some embodiments, the hydrogen donor layer 330 may cover all of the light emitting areas EA1, EA2, and EA3, the spaces SA, and the non-light emitting area BA.

FIG. 5 is a schematic cross-sectional view of the display device taken along line X1-X1′ of FIG. 4.

Referring to FIG. 5, the first substrate 10 of the display device 1 may include a first base substrate 110, a thin film transistor layer 130, and a light emitting element layer 150.

The thin film transistor layer 130 may be positioned on the first base substrate 110.

The thin film transistor layer 130 may include a first buffer layer 111, a lower metal layer BML, a second buffer layer 113, a thin film transistor TFT, a gate insulating layer 131, a first interlayer insulating layer 133, a capacitor electrode CPE, a second interlayer insulating layer 135, a first connection electrode CNE1, a first passivation layer 137, a second connection electrode CNE2, and a second passivation layer 139.

The first buffer layer 111 may be disposed on the first base substrate 110. The first buffer layer 111 may include an inorganic layer capable of preventing permeation of air or moisture. For example, the first buffer layer 111 may include multiple inorganic layers alternately stacked each other.

The lower metal layer BML may be disposed on the first buffer layer 111. For example, the lower metal layer BML may be formed as a single layer or a multi-layer including at least one of molybdenum (Mo), aluminum (Al), chromium (Cr), gold (Au), titanium (Ti), nickel (Ni), neodymium (Nd), copper (Cu), and an alloy thereof.

The second buffer layer 113 may cover the first buffer layer 111 and the lower metal layer BML. The second buffer layer 113 may include an inorganic layer capable of preventing permeation of air or moisture. For example, the second buffer layer 113 may include multiple inorganic layers alternately stacked each other.

The thin film transistor TFT may be disposed on the second buffer layer 113, and may constitute a pixel circuit of each of the pixels. The thin film transistor TFT may be a driving transistor or a switching transistor of the pixel circuit. The thin film transistor TFT may include a semiconductor layer ACT, a source electrode SE, a drain electrode DE, and a gate electrode GE. The thin film transistor TFT may include an oxide TFT and/or a low temperature polysilicon thin film transistor (LTPS).

The semiconductor layer ACT may be disposed on the second buffer layer 113. The semiconductor layer ACT may overlap the lower metal layer BML and the gate electrode GE in the thickness direction, and may be insulated from the gate electrode GE by the gate insulating layer 131. In a portion of the semiconductor layer ACT, a material of the semiconductor layer ACT may become a conductor to form the source electrode SE and the drain electrode DE.

The gate electrode GE may be disposed on the gate insulating layer 131. The gate electrode GE may overlap the semiconductor layer ACT in a plan view, and the gate insulating layer 131 may be interposed between the gate electrode GE and the semiconductor layer ACT.

The gate insulating layer 131 may be disposed on the semiconductor layer ACT. For example, the gate insulating layer 131 may cover the semiconductor layer ACT and the second buffer layer 113, and may insulate the semiconductor layer ACT and the gate electrode GE from each other. The gate insulating layer 131 may include a contact hole through which the first connection electrode CNE1 penetrates.

The first interlayer insulating layer 133 may cover the gate electrode GE and the gate insulating layer 131. The first interlayer insulating layer 133 may include a contact hole through which the first connection electrode CNE1 penetrates. The contact hole of the first interlayer insulating layer 133 may be connected to the contact hole of the gate insulating layer 131 and a contact hole of the second interlayer insulating layer 135.

The capacitor electrode CPE may be disposed on the first interlayer insulating layer 133. The capacitor electrode CPE may overlap the gate electrode GE in the thickness direction. The capacitor electrode CPE and the gate electrode GE may form a capacitance.

The second interlayer insulating layer 135 may cover the capacitor electrode CPE and the first interlayer insulating layer 133. The second interlayer insulating layer 135 may include a contact hole through which the first connection electrode CNE1 penetrates. The contact hole of the second interlayer insulating layer 135 may be connected to the contact hole of the first interlayer insulating layer 133 and the contact hole of the gate insulating layer 131.

The first connection electrode CNE1 may be disposed on the second interlayer insulating layer 135. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer 135, the first interlayer insulating layer 133, and the gate insulating layer 131 and be in contact with the drain electrode DE of the thin film transistor TFT.

The first passivation layer 137 may cover the first connection electrode CNE1 and the second interlayer insulating layer 135. The first passivation layer 137 may protect the thin film transistor TFT. The first passivation layer 137 may include a contact hole through which the second connection electrode CNE2 penetrates.

The second connection electrode CNE2 may be disposed on the first passivation layer 137. The second connection electrode CNE2 may electrically connect the first connection electrode CNE1 and pixel electrodes AE1, AE2, and AE3 of the light emitting element ED1, ED2, and ED3 to each other. The second connection electrode CNE2 may be inserted into the contact hole formed in the first passivation layer 137 and be in contact with the first connection electrode CNE1.

The second passivation layer 139 may cover the second connection electrode CNE2 and the first passivation layer 137. The second passivation layer 139 may include contact holes through which the pixel electrodes AE1, AE2, and AE3 of the light emitting elements ED1, ED2, and ED3 penetrate.

The light emitting element layer 150 may be disposed on the thin film transistor layer 130. The light emitting element layer 150 may include a pixel defining layer 151 defining multiple light emitting areas EA1, EA2, and EA3, and multiple light emitting elements ED1, ED2, and ED3 may be respectively disposed in the light emitting areas EA1, EA2, and EA3. The light emitting element ED1, ED2, and ED3 may each include pixel electrodes AE1, AE2, and AE3, light emitting structures EL1, EL2, and EL3, and a common electrode CE.

The light emitting areas EA1, EA2, and EA3 defined by the pixel defining layer 151 may be defined by multiple first to third openings OP1, OP2, and OP3 of the pixel defining layer 151.

The light emitting elements ED1, ED2, and ED3 may include a first light emitting element ED1 disposed in the first light emitting area EA1, a second light emitting element ED2 disposed in the second light emitting area EA2, and a third light emitting element ED3 disposed in the third light emitting area EA3. The light emitting elements ED1, ED2, and ED3 may emit light of different colors, such as red, blue, green, or white, depending on materials of the light emitting structures EL1, EL2, and EL3. For example, the first light emitting element ED1 disposed in the first light emitting area EA1 may emit red light of a first color, the second light emitting element ED2 disposed in the second light emitting area EA2 may emit green light of a second color, and the third light emitting element ED3 disposed in the third light emitting area EA3 may emit blue light of a third color. Three light emitting areas EA1, EA2, and EA3 constituting one pixel may express a white gradation by including the three light emitting elements ED1, ED2, and ED3 that emit light of different colors.

Each of the pixel electrodes AE1, AE2, and AE3 may be disposed on the second passivation layer 139. Each of the pixel electrodes AE1, AE2, and AE3 may be disposed in an area corresponding to each of the light emitting area EA1, EA2, and EA3. Each of the pixel electrodes AE1, AE2, and AE3 may be electrically connected to the drain electrode DE of the thin film transistor TFT through the first connection electrode CNE1 and the second connection electrode CNE2. The pixel electrodes AE1, AE2, and AE3 may include a first pixel electrode AE1 disposed in the first light emitting area EA1, a second pixel electrode AE2 disposed in the second light emitting area EA2, and a third pixel electrode AE3 disposed in the third light emitting area EA3. The first pixel electrode AE1, the second pixel electrode AE2, and the third pixel electrode AE3 may be spaced apart from each other on the second passivation layer 139. The pixel electrodes AE1, AE2, and AE3 may include indium-tin-oxide (ITO), indium-zinc-oxide (IZO), zinc oxide (ZnO), indium oxide (In₂O₃), or the like, and may include a transparent material having a high work function. In case that the pixel electrodes AE1, AE2, and AE3 are reflective electrodes, the pixel electrodes AE1, AE2, and AE3 may have a stacked structured in which a material layer having the high work function described above and a reflective material layer including silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof are stacked. For example, the pixel electrodes AE1, AE2, and AE3 may have a multilayer structure of ITO/Mg, ITO/MgF, ITO/Ag, or ITO/Ag/ITO, but the disclosure is not limited thereto.

The display device 1 may include a pixel defining layer 151 disposed on the second passivation layer 139 and the pixel electrodes AE1, AE2, and AE3. The pixel defining layer 151 may include multiple openings OP1, OP2, and OP3 that define the light emitting areas EA1, EA2, and EA3. The pixel defining layer 151 may be formed on a front surface of the second passivation layer 139, and a front surface of each of the pixel electrodes AE1, AE2, and AE3 may be exposed by each of the openings OP1, OP2, and OP3.

The pixel defining layer 151 may be formed as a double layer including an inorganic or organic insulating material layer BS1 and an inorganic insulating material layer BS2 including a fluorine-based material.

In an embodiment, the pixel defining layer 151 may be formed as a double layer including an inorganic insulating material layer BS1 including silicon and an inorganic insulating material layer BS2 including a fluorine-based material. For example, the inorganic insulating material layer BS1 may include an inorganic insulating material such as silicon oxide (SiO₂), silicon nitride (Si₃N₄), and silicon oxynitride (Si₂N₂O).

The inorganic insulating material layer BS2 including the fluorine-based material may include inorganic insulating materials such as fluorine-based silicon oxide (F-SiO₂), fluorine-based silicon nitride (F-Si₃N₄), and fluorine-based silicon oxynitride (F-Si₂N₂O) including the fluorine-based material.

In another embodiment, the pixel defining layer 151 may be formed as a double layer including an organic insulating material layer BS1 and an inorganic insulating material layer BS2 including a fluorine-based material. For example, the organic insulating material layer BS1 may include an organic insulating material such as a polyacrylates resin, an epoxy resin, a phenolic resin, a polyamides resin, a polyimides resin, an unsaturated polyesters resin, a poly phenylenethers resin, a polyphenylenesulfides resin, or benzocyclobutene (BCB). The inorganic insulating material layer BS2 including the fluorine-based material may include inorganic insulating materials such as fluorine-based silicon oxide (F-SiO₂), fluorine-based silicon nitride (F-Si₃N₄), and fluorine-based silicon oxynitride (F-Si₂N₂O) including the fluorine-based material. The pixel defining layer 151 according to an embodiment will be described in detail below with reference to the accompanying drawings.

Each of the light emitting structures EL1, EL2, and EL3 may be disposed on each of the pixel electrodes AE1, AE2, and AE3. In the each of the light emitting structures EL1, EL2, and EL3, light may be emitted from the light emitting structures EL1, EL2, and EL3 of the light emitting elements ED1, ED2, and ED3 by the thin film transistor TFT applying a voltage to the pixel electrodes AE1, AE2, and AE3 of each of the light emitting element ED1, ED2, and ED3, and the common electrode CE of the light emitting elements ED1, ED2, and ED3 receiving a common voltage or a cathode voltage.

The light emitting structures EL1, EL2, and EL3 may include a first light emitting structure EL1, a second light emitting structure EL2, and a third light emitting structure EL3 disposed in different light emitting areas EA1, EA2, and EA3. The first light emitting structure EL1 may be disposed on the first pixel electrode AE1 in the first light emitting area EA1, the second light emitting structure EL2 may be disposed on the second pixel electrode AE2 in the second light emitting area EA2, and the third light emitting structure EL3 may be disposed on the third pixel electrode AE3 in the third light emitting area EA3. The light emitting structures EL1, EL2, and EL3 included in the display device 1 may include quantum dots.

The common electrode CE may be disposed on the light emitting structures EL1, EL2, and EL3. The common electrode CE may cover both the light emitting structures ELI, EL2, and EL3 positioned in the light emitting areas EA1, EA2, and EA3 and the pixel defining layer 151. The common electrode CE may include a transparent conductive material so that the light generated from the light emitting structures ELI, EL2, and EL3 may be emitted. The common electrode CE may receive a common voltage or a low potential voltage. In case that the pixel electrodes AE1, AE2, and AE3 receive a voltage corresponding to the data voltage and the common electrode CE receives the low potential voltage, as a potential difference is formed between the pixel electrodes AE1, AE2, and AE3 and the common electrode CE, the light emitting structures EL1, EL2, and EL3 may emit light. The common electrode CE may include a material layer having a low work function, such as Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.). The common electrode CE may further include a transparent metal oxide layer disposed on the material layer having a low work function.

Although not illustrated, the common electrode CE may include a capping layer on the transparent conductive metal layer. The capping layer may serve to protect the transparent conductive metal. For example, the common electrode CE may be a single layer including a conductive metal or a multilayer layer including a conductive metal and a capping layer.

The display device 1 may include a hydrogen donor layer 330 positioned on the common electrode CE. As mentioned above, the hydrogen donor layer 330 may be deposited on the second base substrate 310 and bonded to the first substrate 10 by the sealing portion 50 through a subsequent process.

In some embodiments, the hydrogen donor layer 330 may be positioned in the non-light emitting area BA and the light emitting areas EA1, EA2, and EA3. In other words, the hydrogen donor layer 330 may be configured as a layer that overlaps and is connected to the non-light emitting area BA and the light emitting areas EA1, EA2, and EA3. The hydrogen donor layer 330 may be a single layer or a multilayer layer in which inorganic insulating materials are stacked each other.

The hydrogen donor layer 330 may be disposed in the non-light emitting area BA between the second base substrate 310 and the common electrode CE. In other words, the hydrogen donor layer 330 may overlap the non-light emitting area BA in a plan view and be in contact with the common electrode CE. The hydrogen donor layer 330 may be positioned in the light emitting areas EA1, EA2, and EA3 and overlap the light emitting elements ED1, ED2, and ED3 in a plan view. However, the hydrogen donor layer 330 may be positioned in the light emitting areas EA1, EA2, and EA3 and be spaced apart from the common electrode CE. Accordingly, a space SA may be defined between the hydrogen donor layer 330 and the common electrode CE in the light emitting areas EA1, EA2, and EA3.

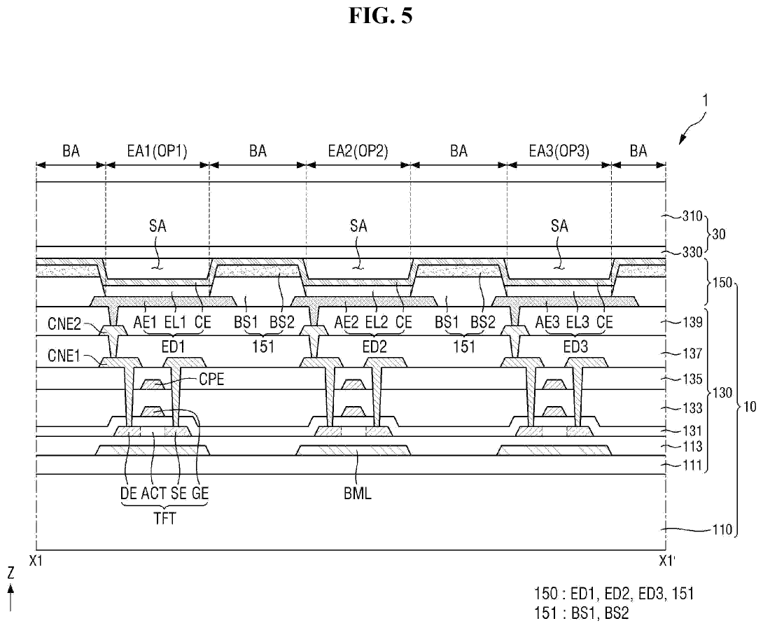

FIG. 6 is a schematic cross-sectional view illustrating a deposition process of a pixel defining layer of FIG. 5.

Referring to FIG. 6, the pixel defining layer 151 may be formed on the front surface of the second passivation layer 139 and the pixel electrodes AE1, AE2, and AE3, and may be formed as a double layer including an inorganic or organic insulating material layer BS1 and an inorganic insulating material layer BS2 including a fluorine-based material. To this end, an inorganic or organic insulating material layer BS1 may be first formed on the front surface of the second passivation layer 139 and the pixel electrodes AE1, AE2, and AE3.

The inorganic or organic insulating material layer BS1 may be formed through a deposition or application process such as a sputtering process, an inkjet printing process, a photo-resistance formation process, or a spin coating process. The inorganic or organic insulating material layer BS1 may be formed with a thickness in a range of about 100 nm to about 1000 nm.

An inorganic insulating material layer BS2 including a fluorine-based material may be formed on the front surface of the inorganic or organic insulating material layer BS1. In an embodiment, the inorganic insulating material layer BS2 may be formed of fluorine-based silicon oxide (F—SiO₂), fluorine-based silicon nitride (F—Si₃N₄), or fluorine-based silicon oxynitride (F—Si₂N₂O) including the fluorine-based material.

In another embodiment, the inorganic insulating material layer BS2 including the fluorine-based material may include hydrofluosilicic acid (H₂Si_{F}6). The inorganic insulating material layer BS2 including the fluorine-based material may be formed through a deposition or application process such as a sputtering process, an inkjet printing process, a photo-resistance formation process, or a spin coating process. The inorganic insulating material layer BS2 including the fluorine-based material may be formed to have a thickness thinner than a thickness of the inorganic or organic insulating material layer BS1, and may be formed with a thickness in a range of about 50 nm to 200 nm.

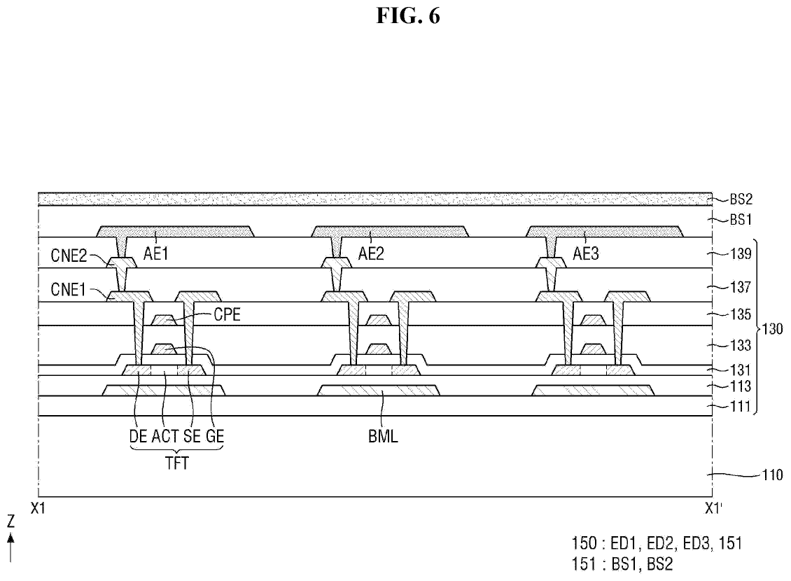

FIG. 7 is a schematic cross-sectional view illustrating a patterning result of the pixel defining layer of FIG. 6.

Referring to FIG. 7, the pixel defining layer 151, in which the inorganic or organic insulating material layer BS1 and the inorganic insulating material layer BS2 including the fluorine-based material are sequentially deposited, may be patterned through a photolithography process or the like. Multiple openings OP1, OP2, and OP3 defining the light emitting areas EA1, EA2, and EA3 may be formed in the pixel defining layer 151 through the patterning process of the pixel defining layer 151. Accordingly, a portion of the front surface of each of the pixel electrodes AE1, AE2, and AE3 may be exposed by each of the openings OP1, OP2, and OP3. By applying and coating the inorganic or organic insulating material layer BS1 with the inorganic insulating material layer BS2 including the fluorine-based material, the inorganic insulating material layer BS2 including the fluorine-based material may stably maintain liquid repellency even in case that the display panel 100 and the pixel defining layer 151 change in high or low temperature. For example, by including the inorganic insulating material layer BS2 including the fluorine-based material in the pixel defining layer 151, the pixel defining layer 151 may stably maintain liquid repellency even under sudden changes in high or low temperature. By including the inorganic insulating material layer BS2 including the fluorine-based material in the pixel defining layer 151, diffusion of fluorine-based components of the photoresist into the pixel defining layer 151 during the photolithography process of the pixel defining layer 151 may be prevented.

Thereafter, light emitting structures EL1, EL2, and EL3 may be formed in the light emitting area EA1, EA2, and EA3 defined by the pixel defining layer 151, respectively. Each of the light emitting structures EL1, EL2, and EL3 may be disposed on each of the pixel electrodes AE1, AE2, and AE3. As described above, the light emitting structures EL1, EL2, and EL3 may include a first light emitting structure EL1, a second light emitting structure EL2, and a third light emitting structure EL3 disposed in different light emitting areas EA1, EA2, and EA3. The first light emitting structure EL1 may be disposed on the first pixel electrode AE1 in the first light emitting area EA1, the second light emitting structure EL2 may be disposed on the second pixel electrode AE2 in the second light emitting area EA2, and the third light emitting structure EL3 may be disposed on the third pixel electrode AE3 in the third light emitting area EA3.

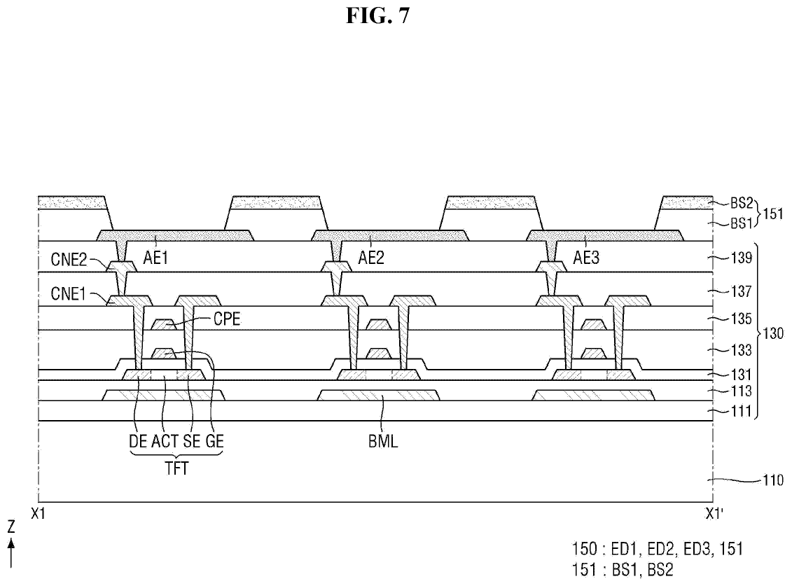

FIG. 8 is an enlarged schematic cross-sectional view of a first light emitting area of the display device illustrated in FIG. 5.

Referring to FIG. 8, the first light emitting structure EL1 of the display device 1 may include a hole injection layer 153, a hole transporting layer 154, a quantum dot light emitting layer 155, and an electron transporting layer 157.

The hole injection layer 153 may be disposed on the pixel electrodes AE1, AE2, and AE3. The hole injection layer 153 may serve to facilitate injection of holes from the pixel electrodes AE1, AE2, and AE3 to the quantum dot light emitting layer 155.

For example, the hole injection layer 153 may include a phthalocyanine compound such as copper phthalocyanine, DNTPD(N,N′-diphenyl-N,N′-bis-[4-(phenyl-m-tolyl-amino)-phenyl]-biphenyl-4,4′-diamine), m-MTDATA(4,4′,4″-[tris(3-methylphenyl)phenylamino] triphenylamine), TDATA(4,4′4″-Tris(N,Ndiphenylamino)triphenylamine), 2-TNATA(4,4′,4″-tris{N,-(2-naphthyl)-N-phenylamino}-triphenylamine), PEDOT/PSS(Poly(3,4-ethylenedioxythiophenc)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPD(N,N′-di(naphthalene-1-yl)-N,N′-diphenylbenzidine), polyether ketone (TPAPEK) including triphenylamine, 4-Isopropyl-4′-methyldiphenyliodonium[Tetrakis(pentafluorophenyl)borate], HAT-CN(dipyrazino[2,3-f:2′,3′-h] quinoxaline-2,3,6,7,10,11-hexacarbonitrile), and the like.

The hole transporting layer 154 may be disposed on the hole injection layer 153. The hole transporting layer 154 may serve to facilitate transport of holes from the pixel electrodes AE1, AE2, and AE3 to the quantum dot light emitting layer 155. The hole transporting layer 154 may include, for example, carbazole-based derivatives such as N-phenylcarbazole and polyvinylcarbazole, fluorene-based derivatives, TPD(N,N′-bis(3-methylphenyl)-N,N′-diphenyl-[1,1-biphenyl]-4,4′-diamine), triphenylamine-based derivatives such as TCTA(4,4′,4″-tris(N-carbazolyl)triphenylamine), NPD(N,N′-di(naphthalene-1-yl)-N,N′-diphenyl-benzidine), TAPC(4,4′-Cyclohexylidene bis [N,Nbis(4-methylphenyl)benzenamine]), HMTPD(4,4′-Bis[N,N′-(3-tolyl)amino]-3,3′-dimethylbiphenyl), mCP(1,3-Bis(N-carbazolyl)benzene), and the like.

The quantum dot light emitting layer 155 may be disposed on the hole transporting layer 154. The quantum dot light emitting layer 155 may include multiple quantum dots.

The quantum dots may adjust the color of emitted light depending on a size of particle, and accordingly, the quantum dots may have various light emitting colors such as blue, red, and green. As the size of the particle of the quantum dots is smaller, the quantum dots may emit light in a short wavelength region. For example, in the quantum dots having the same core, the size of the particle of the quantum dot emitting green light may be smaller than the size of the particle of the quantum dot emitting red light. In the quantum dots having the same core, the size of the particle of the quantum dot emitting blue light may be smaller than the size of the particle of the quantum dot emitting green light. However, the disclosure is not limited thereto, and even in the quantum dots having the same core, the color of emitted light may be adjusted according to a material for forming a shell and a thickness of the shell. In case that the quantum dots have various light emitting colors such as blue, red, and green, the materials of the cores of the quantum dots having different light emitting colors may be different from each other.

The quantum dot particles may have a form of spherical, pyramidal, multi-arm, cubic nanoparticle, nanotube, nanowire, nanofiber, nanoplatelet particle, or the like.

Although not illustrated, the quantum dot light emitting layer 155 may include a core layer including a quantum dot particle and a shell layer surrounding the core layer. The quantum dot particles may be liganded with an inorganic particle on or around a surface of the shell layer. In order to prevent the quantum dot particles from being liganded with the inorganic particles, a hydrothermal treatment process may be further performed on the display panel 100 in which the quantum dot light emitting layer 155 is formed. The hydrothermal treatment process of the quantum dot light emitting layer 155 may be performed through a low-temperature annealing process at lower than or equal to about 100° C. using water vapor, unlike a high-temperature annealing process of 150° C. or higher. During the hydrothermal treatment of the quantum dot light emitting layer 155, it is possible to prevent the quantum dot particles in the quantum dot light emitting layer 155 from being liganded with the inorganic particles.

The embodiment in which the hydrothermal treatment process is performed on the quantum dot light emitting layer 155 after forming the quantum dot light emitting layer 155 including the quantum dot particles is described, but the disclosure is not limited thereto.

The hydrothermal treatment process according to an embodiment of the disclosure may be performed when forming at least one layer including nanoparticles among the hole injection layer 153, the hole transporting layer 154, and the electron transporting layer 157, in addition to the quantum dot light emitting layer 155. In other words, in case that at least one layer of the hole injection layer 153, the hole transporting layer 154, the quantum dot light emitting layer 155, and the electron transporting layer 157 is formed, the hydrothermal treatment process may be performed at least once at lower than or equal to about 100° C. using water vapor.

The core layer of the quantum dot light emitting layer 155 may include a group II-VI compound, a group III-V compound, a group IV-VI compound, a group IV element, a group IV compound, or a combination thereof.

The group II-VI compound may be selected from the group consisting of a binary compound such as CdSe, CdTe, ZnS, ZnSe, ZnTe, ZnO, HgS, HgSe, HgTe, MgSe, MgS, and a mixture thereof; a ternary compound such as AgInS, CuInS, CdSeS, CdSeTe, CdSTe, ZnScS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compound may be selected from the group consisting of a binary compound such as GaN, GaP, GaAs, GaSb, AIN, AIP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAIP, InNP, InNAs, InNSb, InPAs, InPSb, GaAlNP, and a mixture thereof; and a quaternary compound such as GaAlNAs, GaAlNSb, GaAlPAs, GaAlPSb, GalnNP, GalnNAs, GalnNSb, GalnPAs, GalnPSb, InGaAlP, InAlNP, InAlNAs, InAlNSb, InAlPAs, InAlPSb, and a mixture thereof.

The group IV-VI compound may be selected from the group consisting of a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof.

A group IV element may be selected from the group consisting of Si, Ge, and a mixture thereof. A group IV compound may be a binary compound such as SiC, SiGe, and a mixture thereof.

The shell may serve as a passivation layer for maintaining semiconductor properties by preventing chemical modification of the core and/or a charging layer for imparting electrophoretic properties to the quantum dot. The shell layer may include a metal or non-metal oxide, a semiconductor compound, or a combination thereof. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the disclosure is not limited thereto. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the disclosure is not limited thereto.

A diameter of the core layer of the above-described quantum dots may be in a range of about 1 nm to about 10 nm, but the disclosure is not limited thereto. A thickness of the shell layer may be in a range of about 1 nm to about 10 nm, but the disclosure is not limited thereto. The quantum dots included in the quantum dot light emitting layer 155 may be stacked to form a layer. For example, in the quantum dot light emitting layer 155, the quantum dots may be aligned to be adjacent to each other to form one layer, or may be aligned to form multiple layers such as two or three layers.

The electron transporting layer 157 may be disposed on the quantum dot light emitting layer 155. The electron transporting layer 157 may serve to facilitate injection and transport of electrons from the common electrode CE to the quantum dot light emitting layer 155. The electron transporting layer 157 may be formed of a composition for the electron transporting layer, and the composition for the electron transporting layer may include inorganic particles. The inorganic particles may include a metal oxide. In an embodiment, the electron transporting layer 157 of the display device 1 may include ZnMgO or ZnO, but the disclosure is not limited thereto. In another embodiment, the electron transporting layer 157 may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, or Y₂O₃, or a ternary compound such as ZnMgO, MgAl₂O₄, CoFe₂O₄, NiFe₂O₄, CoMn₂O₄, BaTiO₃, BaZrO₃, or ZrSiO₄.

In some embodiments, the hole injection layer 153, the hole transporting layer 154, the quantum dot light emitting layer 155, and the electron transporting layer 157 that constitute the first light emitting structure EL1 may be manufactured through an inkjet printing process. Therefore, the components of the first light emitting structure EL1 may include an inclined portion S that is inclined in a form that climbs up the side surface of the pixel defining layer 151 at a portion in contact with the pixel defining layer 151. In other words, end portions where the first light emitting structure EL1 and the pixel defining layer 151 are in contact may include the inclined portions S that are upwardly inclined in a direction toward the second base substrate 310. For example, the first light emitting structure EL1 may be formed in a U-shape with ends inclined at an angle. For example, since ends of the first light emitting structure EL1 include the inclined portions S, it may be seen that the first light emitting structure EL1 is manufactured through an inkjet process.

The common electrode CE may be disposed on the light emitting structures EL1, EL2, and EL3. The hydrogen donor layer 330 may be formed on the common electrode CE. In some embodiments, the hydrogen donor layer 330 may include an inorganic insulating material with a high hydrogen (H). The hydrogen (H) content of the hydrogen donor layer 330 may be greater than or equal to about 1.0 E+20 molecules/cm³ measured by thermal desorption spectroscopy (TDS). Hereinafter, the expression of hydrogen (H) used in the embodiment may include both hydrogen ions (H⁺) and hydrogen molecules (H₂).

The hydrogen (H) of the hydrogen donor layer 330 may be determined by the ratio of compounds containing hydrogen (H) in the hydrogen donor layer 330. For example, the hydrogen donor layer 330 may be manufactured through a plasma enhanced chemical vapor deposition (PECVD) process, and the hydrogen (H) content of the hydrogen donor layer 330 may be adjusted by changing a composition ratio of a source gas and deposition process conditions.

For example, in case that the hydrogen donor layer 330 is formed of silicon nitride (Si₃N₄), the source gas of silicon nitride (Si₃N₄) may be formed from a combination of silane (SiH₄) and ammonia (NH₃). The process of forming silicon nitride (Si₃N₄) may include molecular hydrogen (H₂) gas. Therefore, in addition to silicon nitride (Si₃N₄), the hydrogen donor layer 330 may include a structure in which hydrogen (H) is bonded to silicon (Si), a structure in which hydrogen (H) is bonded to nitrogen (N), or both structures. In case that the hydrogen donor layer 330 includes silicon oxide (SiO₂) and silicon oxynitride (Si₂N₂O), the hydrogen donor layer 330 may also include a structure in which hydrogen (H) is bonded to oxygen (O). Therefore, the hydrogen (H) content of the hydrogen donor layer 330 may be determined depending on the content of silicon-hydrogen (Si—H) bond, nitrogen-hydrogen (N—H) bond, and oxygen-hydrogen (O—H) bond.

Hydrogen (H) included in the hydrogen donor layer 330 may react with metal oxide included in the light emitting structures EL1, EL2, and EL3 in the display device 1. The hydrogen (H) included in the hydrogen donor layer 330 may serve to improve current characteristics of the display device 1 and increase light emitting efficiency by removing an oxygen vacancy phenomenon of the metal oxide included in the light emitting structure EL1, EL2, and EL3.

For example, the hydrogen (H) included in the hydrogen donor layer 330 may react with zinc magnesium oxide (ZnMgO) or zinc oxide (ZnO) included in the electron transporting layer 157, thereby improving current injection characteristics of the electron transporting layer 157.

In some embodiments, in case that the hydrogen donor layer 330 includes the hydrogen (H) content greater than or equal to about 1.0 E+20 molecules/cm³ measured by thermal desorption spectroscopy (TDS), the hydrogen (H) in the hydrogen donor layer 330 may diffuse in the display device 1 without a separate process.

The hydrogen (H) in the hydrogen donor layer 330 may not only diffuse through the space SA, but may also diffuse through the common electrode CE and the pixel defining layer 151. The hydrogen (H) included in the hydrogen donor layer 330 may pass through the common electrode CE and the pixel defining layer 151 and diffuse into the hole injection layer 153, the hole transporting layer 154, and the quantum dot light emitting layer 155 included in the first light emitting structure EL1. For convenience of explanation, the illustration and description are limited to the first light emitting area EA1, but the hydrogen donor layer 330 and the light emitting elements ED1, ED2, and ED3 in the light emitting areas EA1, EA2, and EA3 may include the same characteristics and structures.

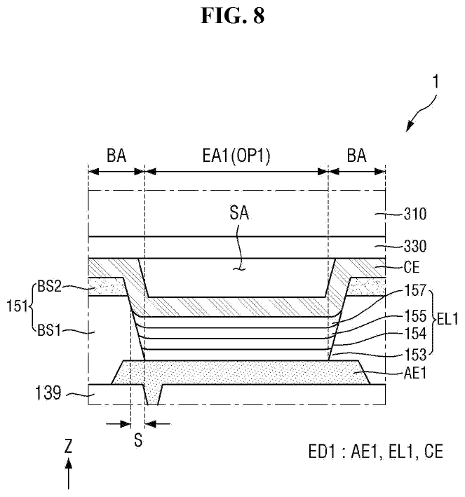

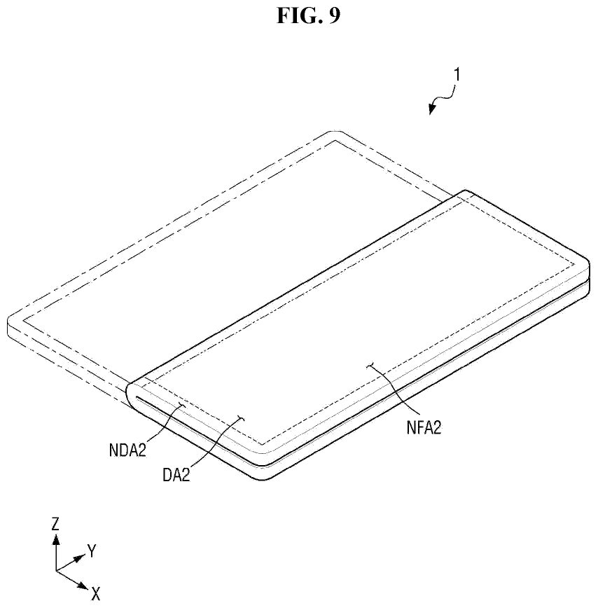

FIGS. 9 and 10 are perspective views illustrating a quantum dot display device including a quantum dot light emitting layer according to an embodiment.

It is illustrated in FIGS. 9 and 10 that the display device 1 is a foldable type quantum dot display device that is foldable in the first direction (X-axis direction). The display device 1 may maintain both a folded state and an unfolded state. The display device 1 may be folded in an in-folding manner in which a front surface is disposed on an inner side. In case that the display device 1 is bent or folded in the in-folding manner, the front surfaces of the display device 1 may be disposed to face each other. In another embodiment, the display device 1 may be folded in an out-folding manner in which the front surface thereof is disposed on an outer side. In case that the display device 1 is bent or folded in the out-folding manner, rear surfaces of the display device 1 may be disposed to face each other.

A first non-folding area NFA1 may be disposed on a side of a folding area FDA, for example, a right side. A second non-folding area NFA2 may be disposed on another side of the folding area FDA, for example, a left side. The pixels PX according to the embodiment of the disclosure may be formed and disposed on the first non-folding area NFA1 and the second non-folding area NFA2, respectively.

A first folding line FOL1 and a second folding line FOL2 may extend in the second direction (Y-axis direction), and the display device 1 may be foldable in the first direction (X-axis direction). Accordingly, since a length of the display device 1 in the first direction (X-axis direction) may be reduced by about half, it may be convenient for the user to carry the display device 1.

The extending direction of the first folding line FOL1 and the extending direction of the second folding line FOL2 are not limited to the second direction (Y-axis direction). For example, the first folding line FOL1 and the second folding line FOL2 may extend in the first direction (X-axis direction), and the display device 1 may be foldable in the second direction (Y-axis direction), and a length of the display device 1 in the second direction (the Y-axis direction) may be reduced by about half. In another embodiment, the first folding line FOL1 and the second folding line FOL2 may extend in a diagonal direction between the first direction (X-axis direction) and the second direction (Y-axis direction) of the display device 1, and the display device 1 may be foldable in a triangular shape.

In case that the first folding line FOL1 and the second folding line FOL2 extend in the second direction (Y-axis direction), a length of the folding area FDA in the first direction (X-axis direction) may be less than a length of the folding area FDA in the second direction (Y-axis direction). A length of the first non-folding area NFA1 in the first direction (X-axis direction) may be greater than the length of the folding area FDA in the first direction (X-axis direction). A length of the second non-folding area NFA2 in the first direction (X-axis direction) may be greater than the length of the folding area FDA in the first direction (X-axis direction).

A first display area DA1 may be disposed on the front surface of the display device 1. The first display area DA1 may overlap the folding area FDA, the first non-folding area NFA1, and the second non-folding area NFA2 in a thickness direction. Therefore, in case that the display device 1 is unfolded, an image may be displayed in a front direction in the folding area FDA, the first non-folding area NFA1, and the second non-folding area NFA2 of the display device 1.

A second display area DA2 may be disposed on the rear surface of the display device 1. The second display area DA2 may overlap the second non-folding area NFA2 in a thickness direction. Therefore, in case that the display device 1 is folded, an image may be displayed in the front direction in the second non-folding area NFA2 of the display device 1.

FIGS. 9 and 10 schematically illustrate that a through hole TH in which a camera or the like is formed is disposed in the first non-folding area NFA1, but the disclosure is not limited thereto. In another embodiment, the through hole TH or the camera may be disposed in the second non-folding area NFA2 or the folding area FDA.

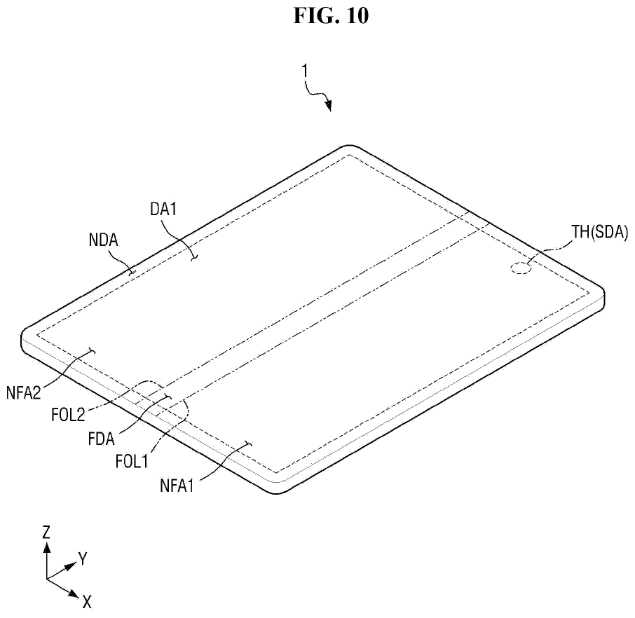

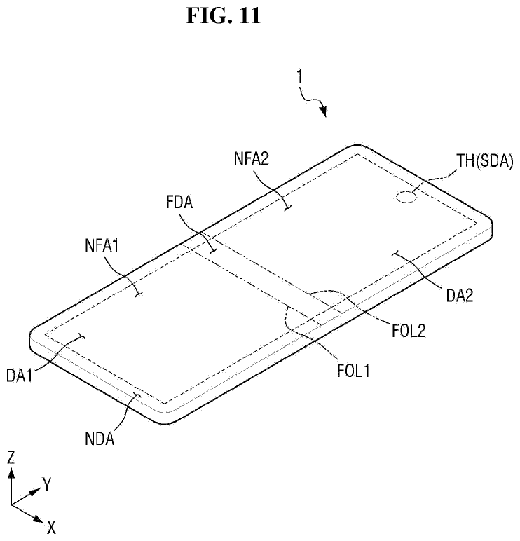

FIGS. 11 and 12 are perspective views illustrating a quantum dot display device according to another embodiment of the disclosure.

It is illustrated in FIGS. 11 and 12 that the display device 1 is a foldable display device that is foldable in the second direction (Y-axis direction). The display device 1 may maintain both a folded state and an unfolded state. The display device 1 may be foldable in an in-folding manner in which a front surface thereof is disposed on an inner side. In case that the display device 1 is bent or folded in the in-folding manner, the front surfaces of the display device 1 may be disposed to face each other. In another embodiment, the display device 1 may be folded in an out-folding manner in which the front surface thereof is disposed on an outer side. In case that the display device 1 is bent or folded in the out-folding manner, rear surfaces of the display device 1 may be disposed to face each other.

The display device 1 may include a folding area FDA, a first non-folding area NFA1, and a second non-folding area NFA2. The folding area FDA may be an area in which the display device 1 is foldable, and the first non-folding area NFA1 and the second non-folding area NFA2 may be areas in which the display device 1 is not foldable. The first non-folding area NFA1 may be disposed on a side of the folding area FDA, for example, a lower side. The second non-folding area NFA2 may be disposed on another side of the folding area FDA, for example, an upper side.

The pixels PX according to the embodiment of the specification may be formed and disposed on the first non-folding area NFA1 and the second non-folding area NFA2, respectively.

On the other hand, the folding area FDA may be an area bendable with a curvature at the first folding line FOL1 and the second folding line FOL2. Therefore, the first folding line FOL1 may be a boundary between the folding area FDA and the first non-folding area NFA1, and the second folding line FOL2 may be a boundary between the folding area FDA and the second non-folding area NFA2.

As illustrated in FIGS. 11 and 12, the first folding line FOL1 and the second folding line FOL2 may extend in the first direction (X-axis direction), and the display device 1 may be foldable in the second direction (Y-axis direction). Accordingly, since a length of the display device 1 in the second direction (Y-axis direction) may be reduced by about half, it may be convenient for a user to carry the display device 1.

The extending direction of the first folding line FOL1 and the extending direction of the second folding line FOL2 are not limited to the first direction (X-axis direction). For example, the first folding line FOL1 and the second folding line FOL2 may extend in the second direction (Y-axis direction), and the display device 1 may be foldable in the first direction (X-axis direction), and a length of the display device 1 in the first direction (the X-axis direction) may be reduced by about half. In another embodiment, the first folding line FOL1 and the second folding line FOL2 may extend in a diagonal direction between the first direction (X-axis direction) and the second direction (Y-axis direction) of the display device 1, and the display device 1 may be foldable in a triangular shape.

In case that the first folding line FOL1 and the second folding line FOL2 extend in the first direction (X-axis direction) as illustrated in FIGS. 11 and 12, a length of the folding area FDA in the second direction (Y-axis direction) may be less than a length of the folding area FDA in the first direction (X-axis direction). A length of the first non-folding area NFA1 in the second direction (Y-axis direction) may be greater than the length of the folding area FDA in the second direction (Y-axis direction). A length of the second non-folding area NFA2 in the second direction (Y-axis direction) may be greater than the length of the folding area FDA in the second direction (Y-axis direction).

A first display area DA1 may be disposed on the front surface of the display device 1. The first display area DA1 may overlap the folding area FDA, the first non-folding area NFA1, and the second non-folding area NFA2 in a thickness direction. Therefore, in case that the display device 1 is unfolded, an image may be displayed in a front direction in the folding area FDA, the first non-folding area NFA1, and the second non-folding area NFA2 of the display device 1.

A second display area DA2 may be disposed on the rear surface of the display device 1. The second display area DA2 may overlap the second non-folding area NFA2 in a thickness direction. Therefore, in case that the display device 1 is folded, an image may be displayed in the front direction in the second non-folding area NFA2 of the display device 1.

FIGS. 11 and 12 illustrate that a through hole TH in which a camera or the like is disposed is disposed in the second non-folding area NFA2, but the disclosure is not limited thereto. In another embodiment, the through hole TH may be disposed in the first non-folding area NFA1 or the folding area FDA.

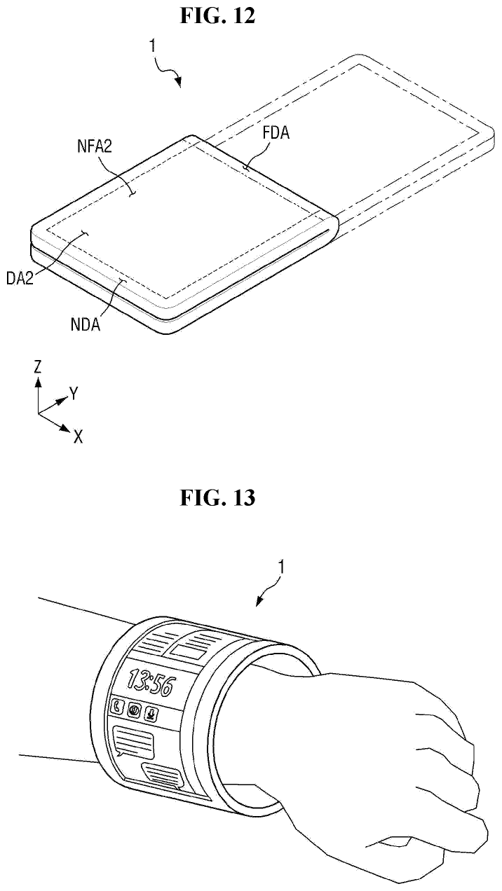

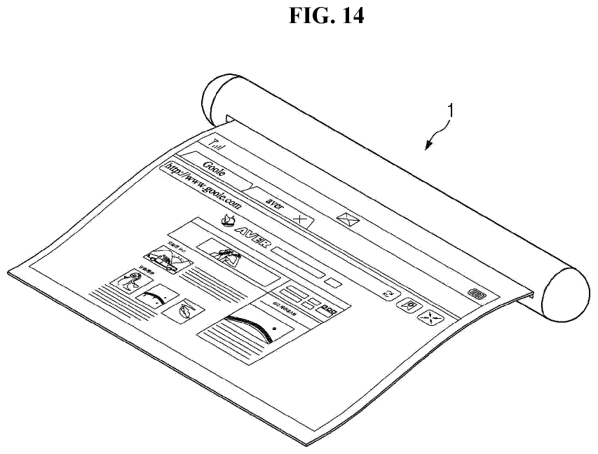

FIG. 13 is a perspective view illustrating a rollable type quantum dot display device according to another embodiment of the disclosure. FIG. 14 is a perspective view illustrating a rollable type quantum dot display device according to another embodiment of the disclosure.

Referring to FIGS. 13 and 14, the rollable type display device 1 may be applied as a display unit of portable electronic devices such as tablet personal computers (PCs), mobile communication terminals, electronic notebooks, e-books, and ultra mobile PCs (UMPCs). A display panel 100 of the rollable type display device 1 may be bendable and rollable in the first direction (X-axis direction) or the second direction (Y-axis direction).

According to the quantum dot display device of the embodiments as described above, reliability of the light emitting elements may be improved by preventing diffusion of impurities in the light emitting elements including the quantum dot particles and the quantum dot light emitting layer. The durability of light emitting elements may be increased by preventing the bonding of ligands of organic or inorganic compounds, such as organic particles or inorganic particles.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate including a light emitting area and a non-light emitting area;
a first pixel electrode disposed on the light emitting area of the first substrate;
a pixel defining layer disposed on the non-light emitting area of the first substrate and the first pixel electrode;
a light emitting structure disposed on the first pixel electrode and including quantum dots; and
a common electrode covering the light emitting structure and the pixel defining layer,
wherein the pixel defining layer includes a first inorganic insulating material layer including a fluorine-based material.

2. The display device of claim 1, further comprising:
an encap structure disposed on the common electrode, overlapping the non-light emitting area in a thickness direction of the first substrate, and in contact with the common electrode, wherein
the encap structure includes a second substrate and a hydrogen donor layer disposed between the second substrate and the common electrode,
the hydrogen donor layer overlaps the light emitting area in the thickness direction and is spaced apart from the common electrode, and
a space is interposed between the hydrogen donor layer and the common electrode.

3. The display device of claim 2, wherein the hydrogen donor layer includes at least one of silicon nitride and silicon oxide, and
the hydrogen donor layer further includes a hydrogen atom forming one of a silicon-hydrogen (Si—H) bond, a nitrogen-hydrogen (N—H) bond, and an oxygen-hydrogen (O—H) bond.

4. The display device of claim 1, wherein
the light emitting structure further includes a quantum dot light emitting layer and an electron transporting layer,
the light emitting structure has an inclined portion inclined in a direction toward the common electrode at a portion in contact with the pixel defining layer, and
the electron transporting layer includes zinc oxide.

5. The display device of claim 1, wherein the pixel defining layer further includes a second inorganic insulating material layer including silicon, and is formed as a double layer with the second inorganic insulating material layer covering the first inorganic insulating material layer.

6. The display device of claim 5, wherein
the second inorganic insulating material layer includes at least one of silicon oxide (SiO₂), silicon nitride (Si₃N₄), and silicon oxynitride (Si₂N₂O), and
the first inorganic insulating material layer includes at least one of fluorine-based silicon oxide (F-SiO₂), fluorine-based silicon nitride (F-Si₃N₄), and fluorine-based silicon oxynitride (F-Si₂N₂O).

7. The display device of claim 1, wherein the pixel defining layer further includes an organic insulating material layer including silicon, and is formed as a double layer with the organic insulating material layer with the first inorganic insulating material layer.

8. The display device of claim 7, wherein
the organic insulating material layer includes at least one of a polyacrylates resin, an epoxy resin, a phenolic resin, a polyamides resin, a polyimides resin, an unsaturated polyesters resin, a polyphenylenethers resin, a polyphenylenesulfides resin, and benzocyclobutene (BCB), and
the first inorganic insulating material layer includes at least one of fluorine-based silicon oxide (F-SiO₂), fluorine-based silicon nitride (F-Si₃N₄), and fluorine-based silicon oxynitride (F-Si₂N₂O).

9. A display device comprising:
a first substrate including a light emitting area and a non-light emitting area;
a first pixel electrode disposed on the light emitting area of the first substrate;
a pixel defining layer disposed on the non-light emitting area of the first substrate and on the first pixel electrode;
a light emitting structure disposed on the first pixel electrode and including quantum dots;
a common electrode covering the light emitting structure and the pixel defining layer; and
an encap structure disposed on the common electrode, overlapping the non-light emitting area in a thickness direction of the first substrate, and in contact with the common electrode,
wherein the pixel defining layer is formed as a double layer including:
an organic insulating material layer or a first inorganic insulating material layer disposed on the non-light emitting area of the first substrate; and
a second inorganic insulating material layer covering the organic insulating material layer or the first inorganic insulating material layer.

10. The display device of claim 9, wherein
the encap structure includes a second substrate and a hydrogen donor layer disposed between the second substrate and the common electrode,
the hydrogen donor layer overlaps the light emitting area in the thickness direction and is spaced apart from the common electrode, and
a space is interposed between the hydrogen donor layer and the common electrode.

11. The display device of claim 10, wherein
the hydrogen donor layer includes at least one of silicon nitride and silicon oxide, and
the hydrogen donor layer further includes a hydrogen atom forming one of a silicon-hydrogen (Si—H) bond, a nitrogen-hydrogen (N—H) bond, and an oxygen-hydrogen (O—H) bond.

12. The display device of claim 9, wherein
the light emitting structure further includes a quantum dot light emitting layer and an electron transporting layer,
the light emitting structure has an inclined portion inclined in a direction toward the common electrode at a portion in contact with the pixel defining layer, and
the electron transporting layer includes zinc oxide.

13. The display device of claim 9, wherein the pixel defining layer is formed as a double layer with the organic insulating material layer or the first inorganic insulating material layer covering the second inorganic insulating material layer including a fluorine-based material

14. The display device of claim 13, wherein
the first inorganic insulating material layer includes at least one of silicon oxide (SiO₂), silicon nitride (Si₃N₄), and silicon oxynitride (Si₂N₂O), and
the second inorganic insulating material layer includes at least one of fluorine-based silicon oxide (F-SiO₂), fluorine-based silicon nitride (F-Si₃N₄), and fluorine-based silicon oxynitride (F-Si₂N₂O).

15. The display device of claim 13, wherein the organic insulating material layer includes at least one of a polyacrylates resin, an epoxy resin, a phenolic resin, a polyamides resin, a polyimides resin, an unsaturated polyesters resin, a polyphenylenethers resin, a polyphenylenesulfides resin, and benzocyclobutene (BCB).
